(19) United States
(12) Patent Application Publication
(10) Pub. No.: US 2005/0112476 A1
(43) Pub. Date: May 26, 2005

(54) Phase-shift mask and fabrication thereof

(76) Inventors: Robert A. Bellman, Painted Post, NY (US); Ljerka Ukrainczyk, Painted Post, NY (US)

Correspondence Address: CORNING INCORPORATED, SP-TI-3-1, CORNING, NY, 14831, US

(21) Appl. No.: 10/950,051

(22) Filed: Sep. 24, 2004

Related U.S. Application Data
(60) Provisional application No. 60/524,465, filed on Nov. 24, 2003.

(51) Int. Cl. G03F 9/00; G03C 5/00

(52) U.S. Cl. 430/5; 430/322

(57) ABSTRACT

Disclosed are phase-shift photomask and method for its fabrication. The phase-shift features of the photomask are formed by using electron-curing sol-gel coatings. Ultra-fine phase-shift features can be created according to the method. The process disclosed is simpler than conventional method for producing phase-shift photomasks.

### CROSS-REFERENCE TO RELATED APPLICATIONS

The present invention claims priority of U.S. Provisional Patent Application Ser. No. 60/524,465, filed on Nov. 24, 2003, entitled “Phase-Shift Mask and Fabrication Thereof,” the content of which is relied upon and incorporated herein by reference in its entirety.

### FIELD OF THE INVENTION

The present invention relates to phase-shift masks and fabrication thereof. In particular, the present invention relates to phase-shift photolithographic masks comprising features created from cured sol-gel materials and fabrication process therefor using electron-beam. The present invention is useful, for example, in the fabrication of phase-shift photomasks and grayscale photomasks.

### BACKGROUND OF THE INVENTION

Photolithography is employed by, inter alia, semiconductor chip manufacturers to transfer integrated circuit patterns through a mask onto a silicon wafer. An exemplary traditional binary mask is a fused silica plate, with an opaque Cr film on it. Openings in the mask, corresponding to the IC features, allow light from an optical projection system (called a stepper because the exposure is a step and repeat process) to irradiate a photosensitive polymer (photoresist) layer coated on the silicon wafer. After resist development, or its selective removal, the silicon is now exposed to allow etching, metal deposition, ion implantation or other processing, followed by removal or “stripping” of the photoresist. To make a modern, complex microprocessor or memory chip requires as many as 20 iterations of this process with different but complementary (and critically aligned) masks (or mask set). One limitation of photolithography is that there is a minimum feature size that can be imaged on the wafer, determined by the optics of the stepper, the wavelength of the imaging light, and the particular process (e.g., contrast of the photoresist material). As the minimum feature size is reduced, speed and density in chips increase substantially as does the cost of the photolithography tool. Fortunately, a number of strategies have been developed to extend the usefulness of any optical lithography generation. One of these optical extensions is the phase-shift mask (PSM). It can enhance resolution beyond the wavelength-imposed diffraction limit. Since some fraction of the light used in lithography is coherent, phase-shift masks work by destructive optical interference to enhance imaging contrast.

The resolution of an image formed by a projection stepper in a photolithography system is defined by the following equation:
R=k₁·(λ/NA) (1)
wherein R is resolution, k₁ is a process-dependent constant, λ is the illumination wavelength, and NA=sin θ is numerical aperture of the projection lens. Depth of focus (DoF) is another important parameter of a photolithography process besides resolution R. Usually a large DoF is desired, because a larger DoF renders the process more tolerant to departure in wafer flatness and photoresist thickness uniformity. DoF is determined according to the following equation:
DoF=k₂·(λ/NA²) (2)
where k₂ is another process-dependent constant.

From the above equations (1), it can be seen that, in order to enhance resolution R, the following approaches may be employed: (i) using a shorter illumination wavelength λ; (ii) using a projection system having a larger numerical aperture NA; or (iii) lowering constant k₁ by improving the process such as by using phase-shift mask or a higher contrast photoresist. However, from equation (2), it can be seen that when numerical aperture NA is increased, DoF is sacrificed.

Phase-shift masks can improve resolution without sacrificing DoF. Since optical interference does not depend critically upon a perfectly focused image, phase-shift masks can actually increase DoF in comparison to traditional Cr masks. Two types of phase-shift masks are commonly used in lithography: alternating aperture phase-shift masks (AAPSM) and embedded attenuating phase-shift mask (EAPSM). FIG. 1 compares the imaging process for a traditional Cr binary mask and a simple form of the alternating aperture phase-shift mask. Each mask has two closely spaced openings. Because the imaging light is an electromagnetic wave, it has both an electric field amplitude and a phase; the radiance or dose needed to expose the photoresist is proportional to the square of this amplitude. When light passes through adjacent apertures in the Cr mask, the amplitude profiles broaden due to diffraction and spatial filtering of the optical system. At the wafer, the electric field amplitudes overlap and interfere constructively because the light is at least partially coherent. At the wafer, the intensity of the light, which is proportional to the total amplitude squared, is large everywhere and the resist will also be exposed between the apertures, blurring the separate features together. In the simple phase-shift mask, light that traverses one of the apertures is phase-shifted 180°. Again the electric field amplitudes of light passing through the two apertures broaden, but because one component is phase-shifted 180°, they interfere destructively, such that the net amplitude of the imaging light becomes zero (or dark) between adjacent apertures or features. The light intensity passing through the separate apertures is now resolved at the wafer and therefore resolution of imaged features is enhanced.

The alternating aperture phase-shift mask is particularly well suited for printing closely spaced lines. Typically, it provides a 50% improvement in resolution compared to traditional binary Cr masks. In a conventional practical mask design, the silica substrate is etched to produce the 180° phase-shift masks, especially when the features to be printed are in complicated circuit patterns. An unwanted result is that the abrupt transition between 0° and 180° always prints as a dark line, and it can bridge or short-circuit isolated lines in some circuit designs. Although there are strategies to circumvent this, implementing them adds complexity to the mask design, especially for intricate circuits.

FIGS. 2A, 2B and 2C show plan, side elevation (along line A) and end elevation (along line B) views of the result of steps in construction of an alternating aperture PSM as currently implemented commercially. A substrate 10 is made of a material such as a fused silica plate or other stable material which must be transparent to the light used in the photolithography for a transmission mask. The substrate 10 coated with an opaque (“chrome”) film 12 in which openings 14 and 16 have been opened by normal photoresist application, exposure and development, followed by chrome etch to form a conventional chrome-on-glass (COG) photomask. After stripping the original photoresist, the photomask is then recoated with a resist film and apertures are opened in the resist film at the locations of apertures which will be phase-shifted. The openings in this second resist film are larger than those in the underlying chrome to accommodate possible mis-registration. The photomask is then etched and the chrome 12 exposed in the resist openings is used as a mask to etch the underlying substrate 10 to a depth below the original surface to make the depressions after the etching of the substrate 10. The depth of the features etched in the substrate 10 is carefully chosen on the basis of the wavelength of the light to be used in the photolithography and the difference in the index of refraction of the material of the substrate and the ambient atmosphere in which the phase-shift mask is used.

The other type of phase-shift mask is the embedded attenuating phase-shift mask (EAPSM). It is schematically illustrated in FIG. 3A. This mask allows some (typically 6-18%) of the imaging illumination, phase-shifted 180°, to be transmitted by the mask in the normally opaque areas of a corresponding Cr binary mask. Again, even though the out of phase electric field amplitude is only a fraction of the non-shifted light amplitude passing though the aperture, their profiles interfere destructively (net amplitude is zero between apertures) and sharper contrast and improvement in DoF is achieved in imaging. While attenuating phase-shift masks do not afford as much resolution enhancement as the fully transparent alternating aperture masks, they can be fabricated to work for complex circuit patterns using conventional mask making techniques, making them attractive for replacement of Cr binary masks when printing features with sub-wavelength resolution. EAPSMs are particularly suited for printing contacts and isolated clear circuit features with special off-axis illumination. The production of the EAPSMs involves multiple steps of resist deposition, exposure, development, stripping, as well as deposition and etching of Cr and phase shift thin films. FIG. 3B illustrates schematically the steps for producing a typical EAPSM using TiSiN as the attenuating phase-shifting material.

Chromeless phase-shift mask has been developed recently in chromeless phase lithography (CPL). CPL uses chromeless features on the masks to define patterns that have nearly 100% transmission and are phase shifted by 180°. FIG. 4 is a schematic illustration of how a chromeless mask functions. The phase shift is created by etching the silica substrate of the mask to a depth that is dependent on the wavelength of the imaging system. Using the etched silica to induce a phase shift, it is possible to build the desired 100% transmission phase structures for any given wavelength using standard chrome on silica substrates. CPL of this type usually requires a higher NA and a strong off-axis illumination in order to form the high contrast aerial images.

In the production of all of the prior art phase-shift masks, very complex multi-step resist deposition, exposure, development and stripping are required.

In a phase-shift mask to be used in an ambient having a refractive index of about 1, such as in air or N₂, in order to obtain a near 180° phase shift, the following requirement must be met:
d·(nₛ−1)≈λ/2 (3)
where d is the thickness of the phase-shifting film deposited on top of the substrate in an EAPSM, or the height of the phase-shifting steps in a chromeless phase-shift mask or an AAPSM, nS is the refractive index of the phase-shifting film in an EAPSM or the substrate in a chromeless phase-shift mask or AAPSM, and λ is the illumination wavelength.

The phase shifting approach offers great resolution improvement for a 25 nm gate length silicon-on-insulator (SOI) devices using a 248-nm stepper. This method has a deep subwavelength potential. SOI transistors with polysilicon gate lengths of 90, 25 and 9 nm have been demonstrated manufacturable by this approach using a 248-nm stepper. However, for the reasons mentioned above, this approach has so far suffered from impediments such as high mask cost, long turnaround time and difficult inspectability/repair.

Therefore, there remains a genuine need of a phase-shift mask and a production method thereof that overcome the drawbacks of the current phase-shift masks described above.

### SUMMARY OF THE INVENTION

A first aspect of the present invention is a mask having a pattern P₀ transferable onto an image-receiving substrate when subjected to illumination radiation in a lithographic process, comprising a substrate S₀ bearing on a surface thereof patterned phase shift features P₁ formed by a cured sol-gel material, wherein the sol-gel material has a refractive index n₁ and a thickness d at the wavelength of the illumination radiation λ.

In a preferred embodiment, in the mask of the present invention, the refractive index n₁ and thickness d of the phase-shift features P₁ are chosen such that d·(n₁−n₀)≈λ/2, where n₀ is the refractive index of the medium in which the mask is placed when being used, whereby a near 180° phase-shift is created relative to the medium in which the mask is used. Where the medium is air or N₂, n₀≈1. In one embodiment, pattern of the phase-shift features formed by the cured sol-gel is a grating having a pitch of less than 300 nm. In another embodiment, above the surface of the substrate S₀ and/or the phase-shift features P₁ of the mask of the present invention, there exist additional feature patterns P₂ formed by materials opaque or attenuating to the illumination radiation used in the lithographic process. Such opaque material may be, for example, Cr or modified Cr. And the attenuating material may create 180° phase shift with respect to the medium in which the mask is placed during the lithographic process. The phase-shift features P₁ and the additional features P₂ may supplement and/or correct each other when the overall image pattern P₀ is transferred to the image-receiving substrate in a lithographic process.

In an embodiment of the mask of the present invention, the substrate S₀ is a plate having flat surfaces formed by fused silica, doped fused silica and/or low-expansion glass-ceramic materials used in typical photomasks for deep and vacuum UV lithography.

In a preferred embodiment, in the mask of the present invention, the sol-gel material forming the phase-shift features P₁ is obtained from electron beam curing a sol-gel composition of at least one precursor material comprising at least one hydrolysable compound (I) having the following formula
Rₘ-M-Xₙ (I),
where M is a metal or metalloid having a valence of m+n, R independently is a non-hydrolysable group, X is a hydrolysable group, m is an integer from 0 to m+n−1, inclusive, and n is an integer from 1 to m+n, inclusive. Preferably, M is selected from the group consisting of Si, Ti, Al, Ge, Ta, B, Ga, Zr and Sb. Preferably, R is independently a C₁-C₁₂ group, optionally fluorinated. Preferably, X is independently selected from hydrogen, hydroxy, halogen (more preferably chlorine) and C₁-C₄ alkoxy groups. More preferably, n≧2 and all X groups are OR′ where R′ is a C₁-C₄ alkyl group. Preferably, the precursor material of the sol-gel composition comprises 3,3,3-trifluoropropyl trimethoxysilane. Preferably, the precursor material of the sol-gel composition comprises at least one compound (II) which is a compound (I) in which m=0. More preferably, the precursor material of the sol-gel composition comprises, in addition to at least one compound (II), at least one compound (III) which is a compound (I) in which R is independently a non-hydrolysable organic group and m≧1. More preferably, the precursor material of the sol-gel composition comprises, in addition to at least one compound (II), a compound (IV) which is a compound (I) in which R is independently a fluorinated alkyl or phenyl group, and m≧1. Where such a mixture of compounds (II) and (IV) is used, the molar ratio of compounds (II) to (IV) is preferred to be at least 50:50, more preferably at least 70:30.

A second aspect of the present invention is a process for making a phase-shift mask having a pattern P₀ transferable onto an image-receiving substrate when subjected to illumination radiation in a lithographic process having a wavelength λ, said pattern P₀ including a phase-shift pattern P₁, comprising the following steps:
(a) providing a substrate S₀ transparent to the lithographic wavelength λ of the lithographic process in which the mask is used;
(b) depositing on a surface of S₀ a sol-gel film S₁ obtained from at least one precursor material comprising at least one hydrolysable compound (I) having the following formula
   Rₘ-M-Xₙ (I),
   where M is a metal or metalloid having a valence of m+n, R independently is a non-hydrolysable group, X is a hydrolysable group, m is an integer from 0 to m+n−1, inclusive, and n is an integer from 1 to m+n, inclusive;
(c) selectively curing part of the sol-gel film S₁ by exposing the film S₁ selectively to an electron beam, whereby producing a film S₂ consisting of (i) cured parts having the pattern P₁ of desired phase shift features having a refractive index n₁ at the lithographic wavelength λ and a thickness d, and (ii) parts P₃ that are not electron beam cured;
(d) contacting the film S₂ with a solvent to remove the parts P₃ that are not electron beam cured; and
(e) optionally, forming additional pattern features on the substrate S₀ by depositing films of materials opaque or attenuating to the illumination radiation.

In a preferred embodiment of the process of the present invention, the cured parts P₁ in step (c) has a thickness d and refractive index n₁ such that d·(n₁−n₀)≈λ/2, where n₀ is the refractive index of the medium in which the mask is placed at the lithographic wavelength λ when being used.

In a preferred embodiment of the process of the present invention, in step (b), the sol-gel film S₁ is deposited on the surface of S₀ by spin coating or dip coating, preferably by spin coating. Preferably, the film S₁ has a uniform thickness, which leads to a uniform thickness of the electron beam cured phase-shift features P₁.

In a preferred embodiment, step (e) is carried out, and this step comprises depositing a film of a material opaque or attenuating to the illumination radiation used in the lithographic process above the upper surface of S₀ and/or P₁, depositing a photoresist on top of the opaque/attenuating film, exposing the photoresist, developing the exposed photoresist, selectively etching the opaque/attenuating film, followed by stripping the remaining photoresist, whereby additional pattern features P₂ of the opaque/attenuating material are formed. In a preferred embodiment, materials attenuating to the lithographic radiation is used to form at least part of the additional pattern features P₂. The additional pattern features P₂ comprising such materials are chosen to have a thickness d₂ and a refractive index n₂ at the lithographic wavelength λ, such that d·(n₁−n₀)≈λ/2, whereby the attenuating features cause 180° phase-shift of the lithographic radiation with respect to the medium in which the mask is used. In yet another preferred embodiment, materials opaque to the lithographic radiation is used to form at least part of the additional pattern features P₂. Such opaque material can advantageously be a metal Cr layer, or a modified Cr layer, for example, a Cr layer with modified surface, such as an oxidized surface.

In a preferred embodiment of the process of the present invention, in step (a), the transparent substrate S₀ is a plate having flat surfaces made of fused silica, doped fused silica or low expansion glass-ceramic materials.

In one embodiment of the process of the present invention, step (e) is performed after step (b), (c) and (d). In another embodiment of the process of the present invention, step (e) is performed before step (b).

In the process of the present invention, in the sol-gel composition, in the at least one hydrolysable compound (I), M is preferably selected from the group consisting of Si, Ti, Al, Ge, Ta, B, Ga, Zr and Sb. Preferably, R is independently a C₁-C₁₂ group, optionally fluorinated. Preferably, X is independently selected from hydrogen, hydroxy, halogen (preferably chlorine) and C₁-C₄ alkoxy groups. More preferably, n≧2 and all X groups are OR′ where R′ independently is a C₁-C₄ alkyl group. Preferably, the precursor material of the sol-gel composition comprises 3,3,3-trifluoropropyl trimethoxysilane. Preferably, the precursor material of the sol-gel composition comprises at least one compound (II) which is a compound (I) in which m=0. More preferably, the precursor material of the sol-gel composition comprises, in addition to at least one compound (II), at least one compound (III) which is a compound (I) in which R is independently a non-hydrolysable organic group and m≧1. More preferably, the precursor material of the sol-gel composition comprises, in addition to at least one compound (II), at least one compound (IV) which is a compound (I) in which R is independently a fluorinated alkyl or phenyl group, and m≧1. Where such a mixture of compounds (II) and (IV) is used, the molar ratio of compounds (II) to (IV) is preferred to be at least 50:50, more preferably at least 70:30.

The mask and method of the present invention can overcome the drawbacks of conventional phase-shift masks in terms of cost and turnaround time. The sol-gel film S₁ is easy to be deposited with highly uniform thickness. The phase-shift features P₁ having various complex patterns can be readily formed by electron beam curing and simple washing by using solvent. The thus cured sol-gel phase-shift pattern P₁ can have a very uniform thickness and a very low surface roughness. In the mask of the present invention, very fine phase-shift features can be created by using electron beam cure. Compared to conventional phase-shift masks manufacture process, the process of the present invention uses less steps of CVD film deposition, resist coating, baking, developing and stripping and reactive ion etching.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification.

### BRIEF DESCRIPTION OF THE DRAWINGS

In the accompanying drawings,

FIG. 1 is a schematic illustration of the operating principle of a traditional binary mask and a simple alternating aperture phase-shift mask.

FIGS. 2A, 2B and 2C are schematic illustration of the plan, side elevation (along line A) and end elevation (along line B) views, respectively, of an alternating aperture phase-shift mask.

FIG. 3A is a schematic illustration of the operating principle of an attenuating phase-shift mask.

FIG. 3B is a schematic illustration of the manufacture steps of an attenuating phase-shift mask, using TiSiN as the attenuating phase-shift material.

FIG. 4 is a schematic illustration of chromeless phase-shift mask and alternating aperture phase-shift mask in use.

FIG. 5 is a schematic illustration of the cross-section of an exemplary mask of the present invention.

FIG. 6 is a schematic illustration of the design of a traditional alternating aperture phase-shift mask.

FIG. 7-23 are microscopic images of the patterns formed by electron beam curing of sol-gel materials suitable for use in the mask and the process of the present invention.

### DETAILED DESCRIPTION OF THE INVENTION

Sol-gel materials are well known. They have been used in the production of anti-reflective coatings for optical devices, such as photovoltaic systems. WO 02/17347 discloses sol-gel materials, electron beam curing of such sol-gel materials and use thereof in forming ultra-fine features in the micro or nanometer range in certain devices, the relevant portions thereof are relied upon and incorporated herein by reference in their entirety.

In the conventional processes for making phase-shift photomasks, described supra, the phase-shift features are created either by selective reactive ion etching of the photomask substrate, or by chemical vapor deposition of a phase-shift layer, followed by coating, baking, exposure, development of photoresist, selective reactive ion etching of the phase-shift layer, and stripping of the photoresist. As can be readily appreciated by those skilled in the art, these techniques are highly complex and usually very costly. Conditions in these processes must usually be strictly controlled in order to produce phase-shift masks with satisfactory quality and yield.

By using the technique of electron beam curing of sol-gel materials, the present inventors have found an unconventional, convenient, less costly way to produce phase-shift masks. In general terms, the process of the present invention for making a phase-shift mask having a pattern P₀ transferable onto an image-receiving substrate when subjected to illumination radiation in a lithographic process having a wavelength λ, said pattern P₀ including a phase-shift pattern P₁, comprises the following steps:
(a) providing a substrate S₀ transparent to the lithographic wavelength λ of the lithographic process in which the mask is used;
(b) depositing on a surface of S₀ a layer of sol-gel composition film S₁ comprising at least one hydrolysable compound (I) having the following formula
   Rₘ-M-Xₙ (I),
   where M is a metal or metalloid having a valence of m+n, R independently is a non-hydrolysable group, X is a hydrolysable group, m is an integer from 0 to m+n−1, inclusive, and n is an integer from 1 to m+n, inclusive;
(c) selectively curing part of the sol-gel film S₁ by exposing the film S₁ selectively to an electron beam, whereby producing a film S₂ consisting of (i) cured parts having the pattern P₁ of desired phase shift features having a refractive index n₁ at the lithographic wavelength λ and a thickness d, and (ii) parts P₃ that are not electron beam cured;
(d) contacting the film S₂ with a solvent to remove the parts P₃ that are not electron beam cured; and
(e) optionally, forming additional pattern features on the substrate S₀ of materials opaque or attenuating to the illumination radiation.

The steps will be described in detail as follows.

In step (a), the transparent substrate S₀ can be made of any material used for manufacturing conventional masks. The bottom line is the substrate S₀ should be transparent to the lithographic wavelength λ of the lithographic process. Preferably, at the lithographic wavelength λ of the lithographic process, the substrate has a transmission of at least 70%, more preferably at least 75%, most preferably at least 80%. In traditional photomasks, the standard substrate material was soda lime glass. Later, white crown was introduced to reduce defects. And still later, borosilicate glass was introduced to reduce temperature effects on the mask. Currently, as the lithographic wavelength has gone shorter, fused silica has been introduced for further temperature effects and to give better transmission. For the purpose of example and illustration only, the substrate S₀ in the present invention process can be made of borosilicate glass, fused silica, doped fused silica, low thermal expansion optical glass-ceramic materials, etc. For masks used in 248-nm and shorter wavelength photolithography, the substrate is advantageously made of fused silica or doped fused silica. Advantageously, the surfaces of the substrates S₀ have a flatness that meets the requirement of optical distortion in mask manufacture. However, where necessary, the surfaces of substrate S₀ may be engineered to any specific topography before the deposition of the photosensitive film in step (b) by using methods known in the art, such as dry etching and wet etching. Preferably, the thickness of the substrate S₀ is sufficient to satisfy the requirement for gravitational sag and pattern placement accuracy. Preferably, the substrate S₀ has a chemical durability that can withstand the mask producing environment, such as wet etching and dry etching.

Step (b) of the present invention mask-making process involves deposition of a film S₁ of a sol-gel composition on a surface of the substrate S₀. The sol-gel composition is typically an aqueous material system of a precursor material comprising at least one hydrolysable compound having the general formula (I) above. The element M in the compound is a network forming element, such as Si, Ti, Al, Ge, Ta, B, Ga, Zr or Sb. This compound (I) may contain, where m≧1, non-hydrolysable group R. Preferably, the hydrolysable group X is independently selected from hydrogen (preferably chlorine), hydrogen, hydroxy and OR′, where R′ is a C₁-C₄ alkyl. The group X in the compound, when in an aqueous medium, in the presence of acid or base catalyst where necessary, undergoes hydrolysis reaction through either an electrophillic reaction mechanism or a nucleophillic reaction mechanism to form compounds having hydroxies. Condensation reactions between the compounds may further occur to form a network bridged by the —O— linkages. Taking compound Si(OR′)₄ for example, a simplified illustration of several possible reactions is provided as follows:

Hydrolysis:

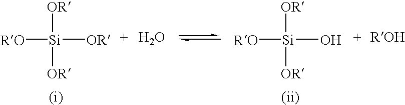

Water Condensation:

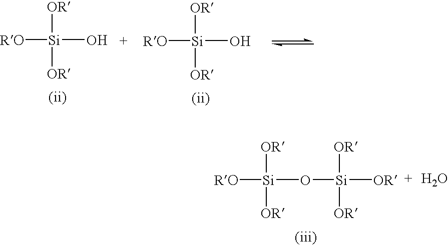

Alcohol Condensation:

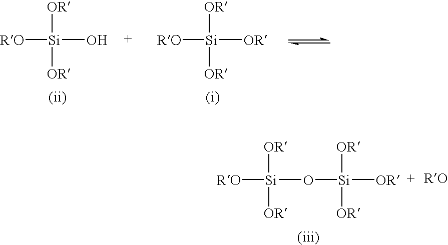

As can be understood by one skilled in the art, further hydrolysis and condensation reactions of compounds (i), (ii) and (iii) may take place via substantially the same mechanism. As a result, a complex network of condensed compounds can be formed. Thus the sol-gel composition as used in step (b) may comprise the hydrolysable compound (I), water, acid or base catalysts as typically used in sol-gel technology, alcohol and condensed products. The degree of condensation between the compounds in the composition is dependent on the chemical nature of the hydrolysable compound (I), nature and amount of catalyst used, nature and amount of optional components, such as alcohols, storage time and temperature, and other factors. Standard procedures of preparation of sol-gel compositions may be employed. For example, it can be prepared by mixing predetermined amounts of compound (I), acid or base catalyst and alcohol into deionized water, followed by aging at a given temperature for a given period of time before application to the photomask substrate. Where the at least one compound (I) comprises chlorine as the X group, it may not be necessary to add additional acid catalyst, insofar as the chlorine group hydrolyses to form HCl, which can act as the catalyst.

It is understood that, from the above reaction scheme, the more hydrolysable groups X the compound (I) has, the more OH can be generated on the molecule by hydrolysis, and a more highly condensed network can be formed. Thus it is desirable that a high proportion of compounds (I), where more than one type of compounds (I) is used, are those in which m=0 and all substituents to the element M are hydrolysable, such as tetraethoxysilane (TEOS, Si(OC₂H₅)₄ and tetraisopropoxygermane (TIPG, Ge(OCH(CH₃)₂)₄). For the purpose of convenience of description in the present application, those compounds (I) wherein m=0 are designated as compounds (II).

Compounds (III), which are compounds (I) in which m≧1 and R is a non-hydrolysable organic group, can impart flexibility to the network of the sol-gel material after cure if added. An example of such a compound (III) is methacryloxypropyl trimethoxysilane (MPTS). Sol-gel compositions comprising compounds (III) may also exhibit enhanced roughness, reduced brittleness, and relatively thicker films (up to 10 nanometers or more) may be cured without cracking using the electron-beam patterning and curing technique of the present invention. It is contemplated that in compound (III), at least one R group may be a functional group such as a photopolymerizable group, e.g., a (meth)acrylic group. Where desired, such functional groups can undergo further reactions, such as polymerization, under certain conditions, such as exposure to UV radiation. The addition of compounds (III) to the sol-gel composition can result in cured inorganic/organic hybrid sol-gel film.

In addition to compounds (II), the sol-gel composition as used in the process of the present invention may comprise compounds (IV) where m≧1 and R is independently a fluorinated alkyl or phenyl group. An example of compound (IV) is 3,3,3-trifluoropropyl trimethoxysilane. Sol-gel compositions comprising at least one compound (IV), defined supra, in effective amount, may also provide a highly non-wetting surface to the cured sol-gel film, which is sometimes desired in the production of the phase-shift mask of the present invention. Since the addition of compounds (IV) into the sol-gel composition may lead to a cured film having lower refractive index, such compounds (IV) may be added to tailor the refractive index of the phase-shift features of the mask after cure.

It is highly desired that the sol-gel composition, when applied to the surface of the substrate S₀, is substantially homogeneous in composition.

The method of application of the sol-gel composition to the surface of the substrate S₀ is not critical as long as a coating of uniform composition with desired uniform thickness of film S₁ can be formed. As non-limiting examples of such coating method, mention can be made of spin-coating and dip-coating, with spin-coating being preferred. Spin-coating can result in a very thin film having very uniform thickness under 500 nm. The thickness of the coating can be easily adjusted.

After the sol-gel composition has been deposited to form a film in step (b) of the process of the present invention, the film may be prebaked to partially cure the sol-gel film S₁ in order to stabilize the film on the substrate S₀, and/or to eliminate tackiness at the surface of the substrate. However, a preheating step is not required, and may not be desirable for many sol-gel compositions.

In step (c) of the process of the present invention, a desired phase-shift pattern is formed in the sol-gel film S₁ by selectively curing predetermined areas of the sol-gel film S₁ that correspond to a desired pattern by directing an electron beam at the selected areas of the film. In other words, a desired pattern is written directly into the sol-gel film using an electron beam. An apparatus for patterning and curing a sol-gel film by writing the desired pattern directly into the sol-gel film using an electron beam can be provided by converting a scanning electron microscope (SEM) (for example, JEOL 840) for use as an electron beam patterning tool using a commercially available SEM conversion package. The commercially available package includes pattern generation software and hardware that directs the electron beam to write patterns that are created by the user in a computer aided design (CAD) software package. A system of this type is capable of writing generally any type of pattern that can be drawn using the CAD software.

Although the mechanism by which curing of the sol-gel film is achieved using an electron beam is perhaps not yet fully understood, it is believed that the electron beam induces localized heating of the sol-gel film, and that this localized heating causes localized curing or condensation of the sol-gel film in those areas of the film bombarded with or exposed to the electron beam by way of the hydrolysis and condensation reactions schematically illustrated above. FTIR studies have shown that e-beam promoted the condensation of silanol groups and localized formation of glass network. It was also observed that in inorganic/organic hybrid sol-gels, e-beam did not cause changes to the organic moieties. The cured areas of the sol-gel film form a condensed three-dimensional network comprised of metal or metalloid atoms linked together through the oxygen atom. The resulting cured product has chemical and physical properties that are very similar, and in some cases almost identical to conventional glasses.

A great advantage of the electronic beam writing process is that ultra-fine phase-shift features, in a nanoscopic dimension, can be created by the electron beam scanning with highly precise control of position and dimension, as demonstrated by the examples of WO 02/17347. Fully cured areas of the film S₁ have a highly uniform thickness that can be controlled by controlling the thickness of the film S₁ when coating the sol-gel composition to the surface of substrate S₀. The cured film can be obtained with a very low surface roughness. In addition, stress-free cured film can be easily obtained by electron beam cure of sol-gel materials. This is beneficial for both the mechanical and optical properties of the phase-shift features of the mask.

For many phase-shift masks, it is desired that the phase-shift features provide a phase-shift amount of near 180°. This can be done, in the process of the present invention, by controlling the thickness d and the refractive index n₁ of the cured sol-gel phase-shift patterns by means described supra, such that they satisfy the equation d·(n₁−n₀)≈λ/2, where λ is the wavelength of the lithographic radiation and n₀ is the refractive index of the medium in which the mask is placed when being used. Where the mask is used in air or N₂, n₀≈1. If the mask is used in a high-refractive-index medium, such as oil, one skilled in the art can adjust d and n₁ accordingly. It is desirable that a strictly 180° phase shift can be obtained. However, in practice, this is difficult, if not impossible, to achieve. Thus as used herein, a 180° or near 180° phase shift amount, is meant to be a phase shift amount of 180±10°, preferably 180±5°, more preferably 180±3°. Where other amounts of phase-shift is desired, such as near 90° or 270°, it can be realized by adjusting the feature thickness and refractive index accordingly. For example, to realize phase shift amounts of near 90° or 270°, the thickness d and refractive index n₁ should satisfy the equation d·(n₁−n₀)≈λ/4 and d·(n₁−n₁)≈3λ/2, respectively.

After the desired pattern P₁ has been written into the sol-gel film S₁ by electron beam scanning, in step (d) of the process of the present invention, the film is contacted with a solvent to dissolve areas of the film that have not been cured. This allows the uncured areas of the film to be easily removed, leaving behind the desired phase-shift pattern of cured sol-gel material. A suitable solvent that may be used to remove the areas of the sol-gel film that have not cured is toluene. In order to improve the wettability and effectiveness of the solvent, the solvent may include a small amount of surfactant. The cured sol-gel pattern P₁ should be transmissive to the illumination radiation used in the lithographic process. Preferably, at the lithographic wavelength λ of the lithographic process, the sol-gel pattern has a transmission of at least 70%, more preferably at least 75%, most preferably at least 80%.

Preferably, the cured sol-gel phase-shift features P₁ has a chemical durability that can withstand the chemical environment of the downstream steps in the process of forming the mask of the present invention, such as the dry etching and/or wet etching steps where necessary. If this is the case, the additional features P₂ can be formed directly by depositing the relevant materials on the upper surface of S₀ and the cured sol-gel pattern P₂. In case the cured sol-gel phase-shift features P₁ is not robust enough to withstand the environment, it is contemplated that a very thin protective layer resistant to the environment, such as a silica layer, may be formed on the upper surface of the cured sol-gel pattern P₁ and optionally on the exposed surface of the substrate S₀ before the formation of additional patterns features P₂ by techniques such as chemical vapor deposition. Of course, the protective layer should be transmissive to the lithographic radiation. As long as the thickness of the protective layer can prevent undesired etch of the cured sol-gel phase-shift pattern P₁, the thinner the protective layer is, the better. In addition, the protective layer should preferably have an even thickness and a low surface roughness in order not to create optical distortion.

The substrate S₀ bearing the cured sol-gel phase-shift features P₁ may be used directly as a phase-shift mask. In such a phase-shift mask, the overall image pattern P₀ is equivalent to the phase-shift feature pattern P₁. Such a simple phase-shift mask can be a simple one- or two-dimensional grating of the phase-shift features. More detailed description of this type of mask will be given infra.

However, in most phase-shift masks, additional features P₂ are formed to combine with the sol-gel phase-shift features P₁ to form the overall image pattern P₀. Such additional features can be formed in the step (e) of the process of the present invention. Such additional features P₂ can be formed by materials opaque or attenuating to the lithographic radiation. For example and for the purpose of illustration only, opaque Cr and/or modified Cr features used on conventional photomasks can be formed. As mentioned above, an intermediate protective layer, particularly an etch stopping layer, such as a silica layer, may be formed between the surface of the cured sol-gel features P₁ before the deposition of the opaque or attenuating layer where necessary, as long as it meets the requirements described above, where the sol-gel features P₁ cannot resist the down-stream photomask forming environment. The formation of such additional opaque or attenuating features P₂ can be effected using methods known in the art, for example, by steps such as depositing a film of the opaque or attenuating material on the surface of the substrate S₀ and/or the phase-shift features P₁, depositing a photoresist on top of the opaque/attenuating film, exposing the photoresist, developing the exposed photoresist, selectively etching the opaque/attenuating film, followed by stripping the remaining photoresist. Deposition of the film of the opaque or attenuating material can be effected via conventional methods such as sputtering, ion plating, and the like. The opaque or attenuating film as deposited may be further modified to obtain a differing etching rate, reflectivity, etc. For example, where part of the additional features P₂ is formed by Cr, the Cr film as deposited may be modified in accordance with U.S. Pat. Nos. 4,530,891 and 4,463,407, the relevant portion of which are incorporated herein by reference, before the lithographic steps are performed on it.

In one embodiment of the process of the present invention, attenuating materials are used to form the additional features P₂. Understandably, the attenuating materials causes phase-shift to the radiation passing through it relative to the medium in which the mask is used, if the refractive indexes of the attenuating material and the medium are not identical. It is desirable in certain phase-shift masks that features formed from these materials create a near 180° phase shift as well.

It is to be noted that in the process of the present invention, step (e) may be carried out after steps (b), (c) and (d). In this case, the phase-shift features P₁ are formed first on the surface of the substrate S₀. Subsequently the additional features P₂ are formed on the remaining area of the surface S₀ and/or on top of the features P₂. Alternatively, the step (e) may be carried out prior to steps (b), (c) and (d). In this embodiment, the additional features P₂ are formed first on a surface of the substrate S₀, and the phase-shift features P₁ formed from sol-gel material are formed thereafter on the remaining area of the surface of the substrate S₀ and/or on top of the features P₂ according to the methods described supra. In this embodiment, pre-formed photomask substrates, such as those bearing Cr or modified Cr films may be used. The combination of P₁ and P₂ forms the overall feature P₀ of the photomask.

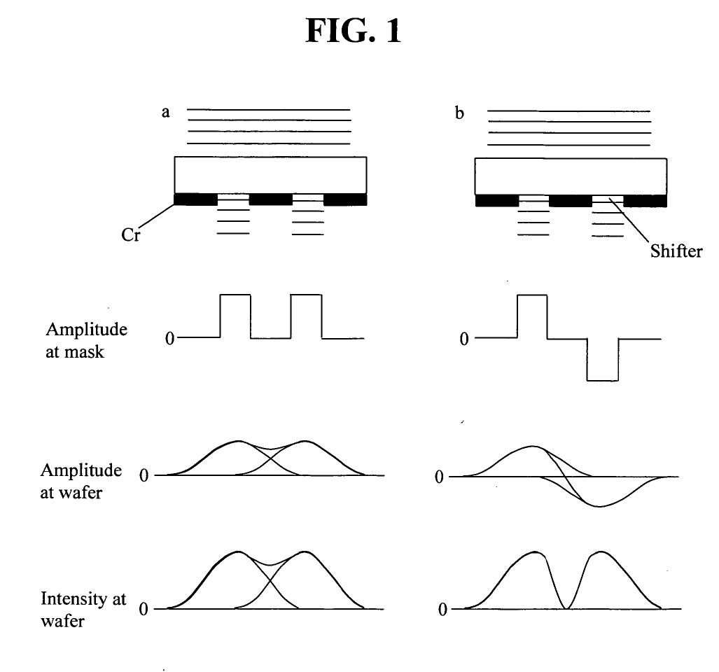

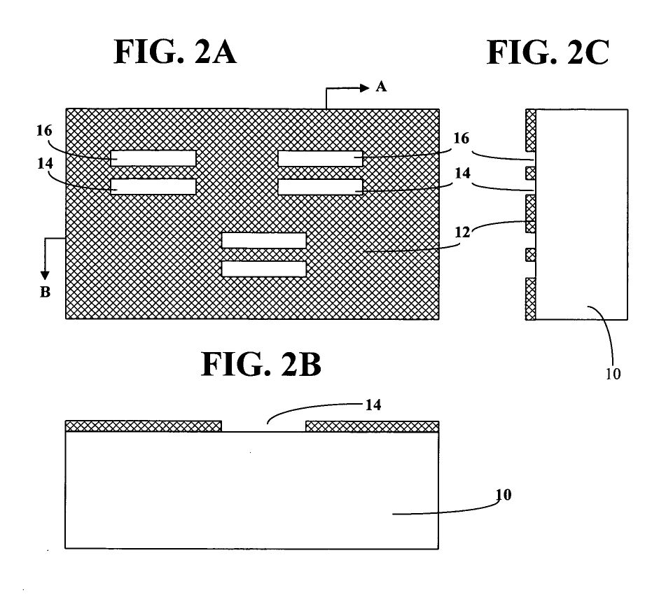

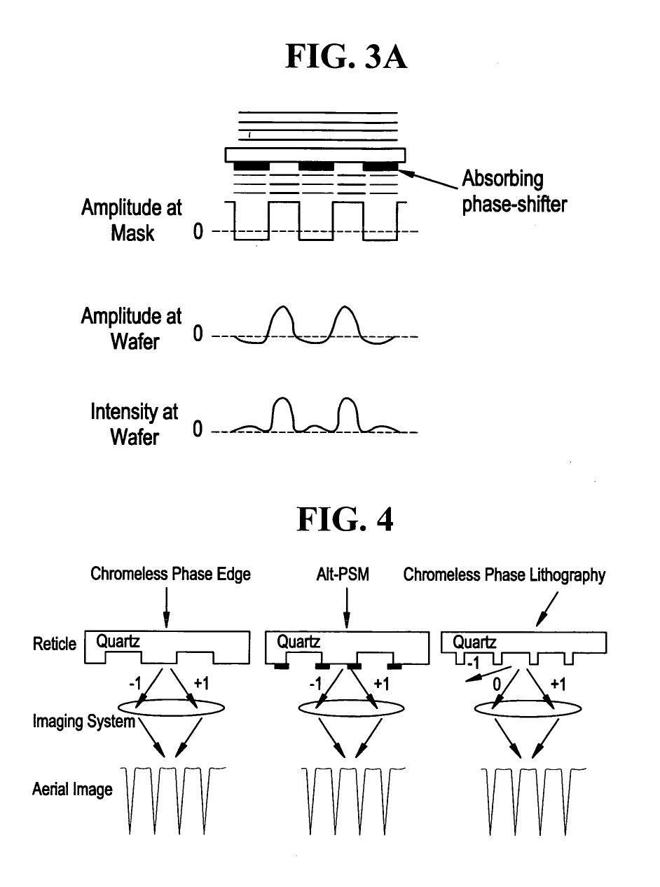

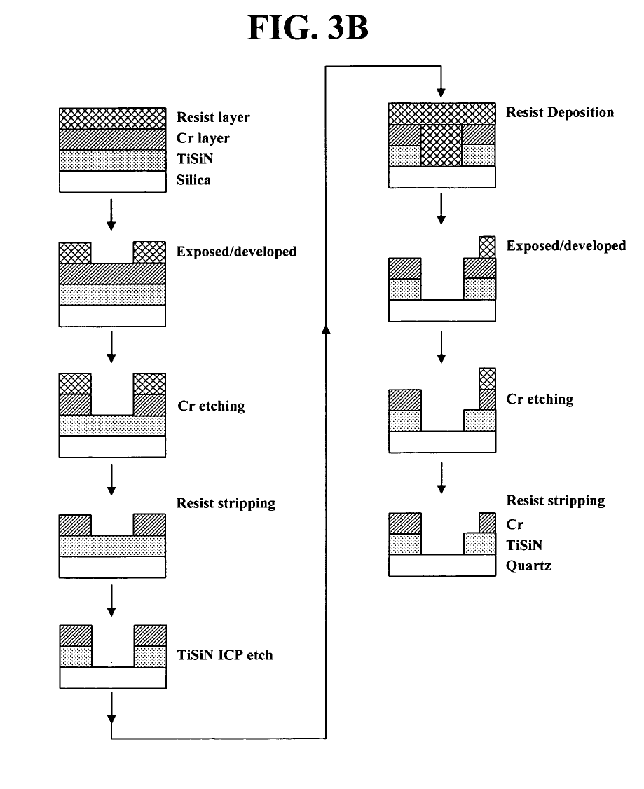

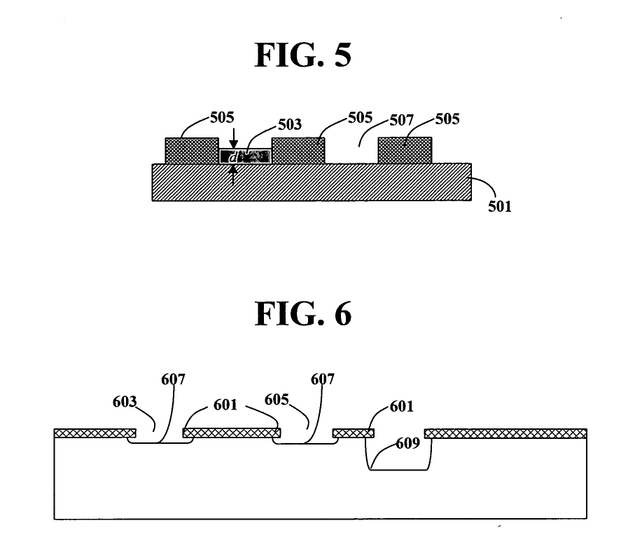

FIG. 5 illustrates schematically the cross-section of a simple phase-shift mask design of the present invention. In this figure, 501 is the transparent substrate S₀. Phase-shift feature 503 having a refractive index n₁ and a thickness d formed by an electron-beam cured sol-gel is formed on the surface of 501. Chrome features 505 are formed as well. As can be readily appreciated by one skilled in the art, the transparent phase shift feature 503 and the aperture 507 between the opaque chrome features 505, when properly formed and located, function according to the principle of an alternating phase-shift mask, which is illustrated in FIG. 1 and described supra.

The production of the FIG. 5 phase-shift mask is simpler than the production of conventional phase-shift masks operating under the similar principle. Also the produced masks have advantages over those of the prior art. FIG. 6 illustrates schematically the design of a conventional PSM corresponding to that of FIG. 5. In FIG. 6, in order to ensure that the two types of aperture perform identically in an optical sense, except for the phase-shift, the substrate is etched back laterally under the opaque film, thus leaving the opaque film unsupported at the edge. The non-phase shifting apertures 603 and 605 and the phase shift apertures are noted. The trenches 607 and 609 etched in the substrate beneath the apertures are necessarily formed after the apertures are etched in the opaque layer, which is a high-cost process. The requirement to form a second custom pattern—by a process that can result in uncorrectable defects—significantly raises the cost of producing this type of conventional alternating aperture PSMs.

Various electronic design automation tools are known for preparing the patterns used in conventional and phase-shift masks. In addition, OPC tools alter those patterns to account for the realities of the exposure systems. It is also known that the pattern of apertures on the phase-shift mask need not correspond closely to the ultimate circuit pattern, at least not when a conventional block-out mask is employed for a second exposure on the resist film in concert with a first exposure made using a an alternating-aperture PSM. Such second exposures erase anomalies due to phase-conflicts. All these tools and strategies developed for conventional masks, phase-shifting or not, can be adapted for use in the production and use of the mask of the present invention.

A specific example of the mask of the present invention involves a grating pattern. The pattern is a 180° phase shifting 1-D or 2-D grating system created by scanning the sol-gel film S₁ with electron beam. The grating pitch can be lower than 300 nm, and may be as short as 100 nm. These low pitch gratings can be used for creating very dense sub-wavelength features. Such mask can be used in conjunction with trim mask and/or chrome binary masks via multiple exposure to create desired image patterns on an image-receiving substrate, such as a wafer. The trim mask can be a phase-shifting trim mask produced using the method of the present invention, or a conventional chrome trim mask. Advantageously, an additional feature P₂ formed by chrome or other weak phase shifting materials is formed to supplement the gratings.

Other various features and advantages of the phase-shift photomask of the present invention can be readily appreciated by reference to the above description of the process for making the same.

The following non-limiting examples further illustrate the present invention.

### EXAMPLES

In these examples, electron-beam patterning of sol-gel films was accomplished by using a custom built electron-beam lithography system. The system was based on a JEOL 840 scanning electron microscope that was converted to write patterns using a commercially available SEM conversion package. The package included pattern generation software and hardware that is used to direct the electron beam to write patterns that are created by the user in a computer aided design (CAD) software package.

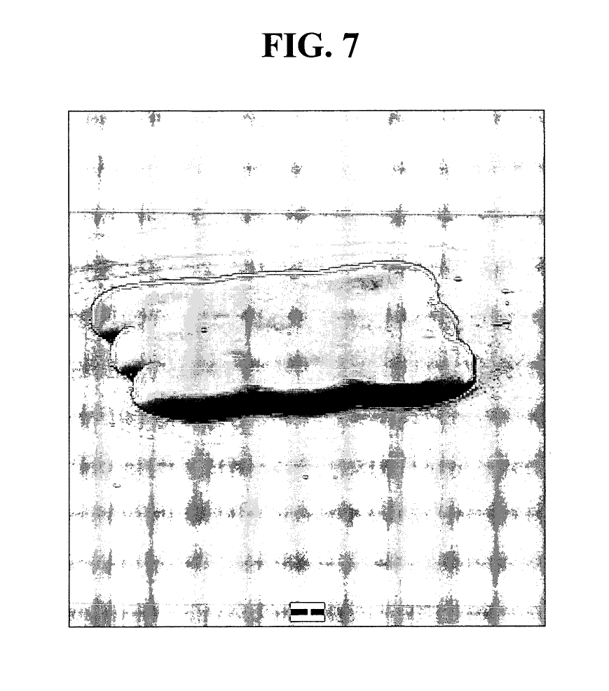

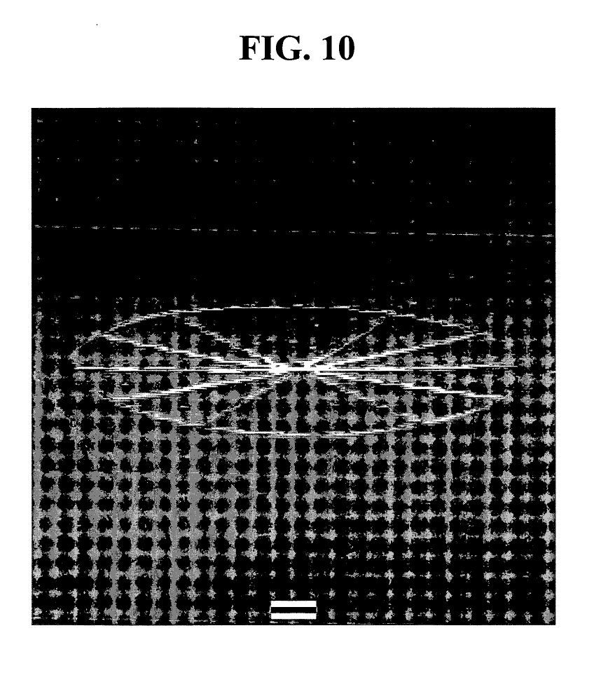

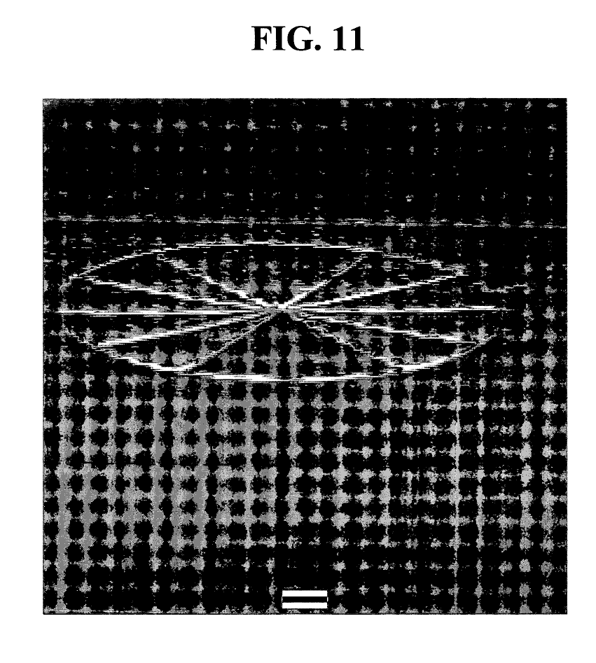

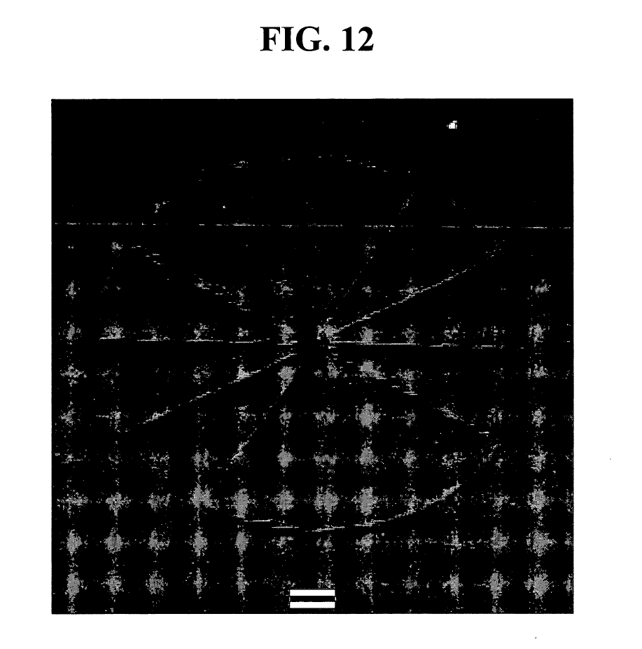

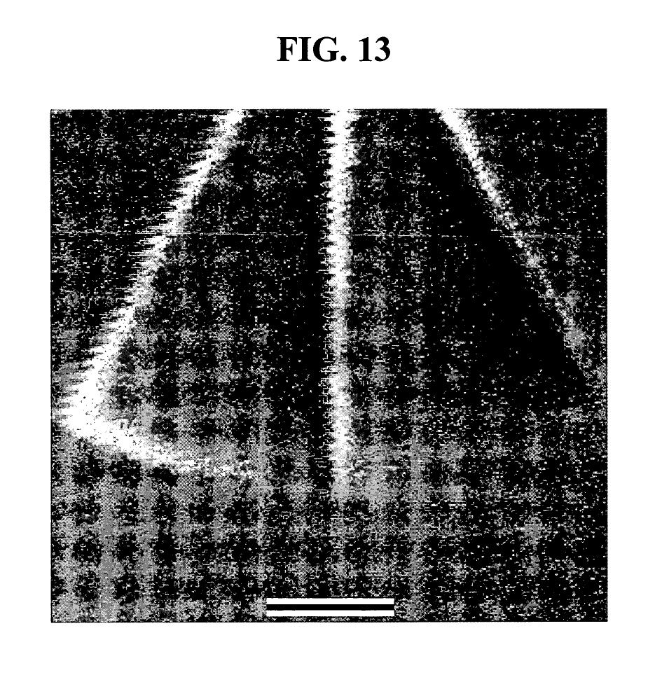

FIGS. 7-13 show scanning electron microscope images of test pattern wheels written using electron-beam lithography into an inorganic-organic hybrid sol-gel material in accordance with the principles of this invention.

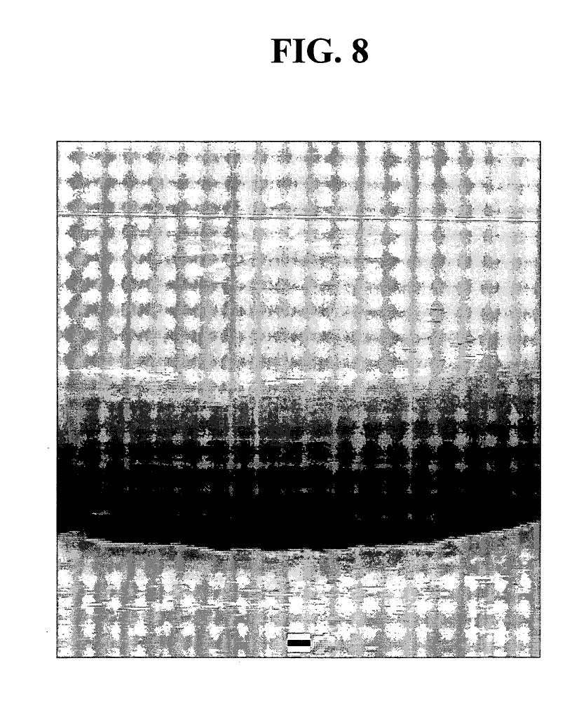

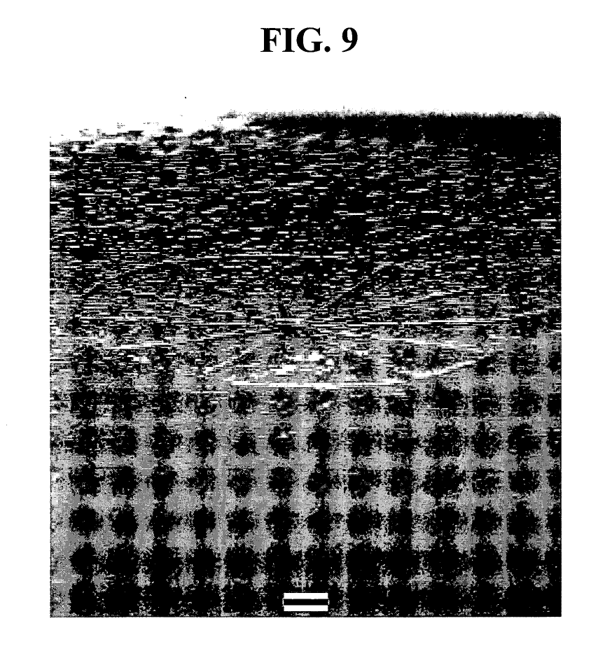

FIG. 7 is an overall view of a 3×3 pattern of wheels and FIGS. 8-13 are magnified images of individual wheels. The wheel patterns shown in FIGS. 9-11 were written at electron-beam dosages of 90, 150, and 270 nC/cm, respectively. The sol-gel composition used in these experiments was comprised of 53.6 mole percent of tetraethoxysilane (TEOS), 13.4 mole percent tetraisopropoxygermane (TIPG), and 33 mole percent methacryloxypropyltrimethoxysilane (MPTS). The composition is UV sensitive on account of the methacryloxy group on the MPTS, and can be patterned with light at 248 nm which crosslinks double bonds on the MPTS. The sol-gel composition was deposited onto a substrate using a spin-coating technique to provide a sol-gel film having a uniform thickness of from about 0.5 to 6 microns. When the sol-gel films were exposed to an electron beam and developed (contacted with a solvent such as toluene to dissolve and remove the area of the film that have not been exposed to, or written with, the electron beam), the film behaved as a negative resist. Infrared spectra of the electron-beam cured film did not show any decrease in the band corresponding to the double bond of MPTS. When the same films were cured by exposure to ultraviolet radiation, infrared spectra indicated that the double bond disappeared. This demonstrates the curing mechanism for electron-beam curing is not by cross-linking of the double bond. In fact, the infrared spectra showed that essentially none of the double bonds in the MPTS were reacted after exposure to an electron beam. An expanded FTIR spectra showed that OH stretch as a function of electron-beam dosage decreased with increasing electron-beam energy. This is consistent with a conventional sol-gel condensation reaction in which a silica framework is formed. It is believed that the electron beam catalyzes the condensation step described above to form a silica glass framework.

In the examples illustrated in FIGS. 7-13, films having a thickness of from 0.5 to 6 microns were used to write lines having a width of about 100 nanometers. FIG. 7 shows a mesa-like structure having the 3×3 wheel pattern written on the top surface of the mesa-like structure. It is believed that electron scattering coupled with thermal conduction cured the surrounding areas of the wheels. The magnified images shown in FIGS. 8-13 show very well defined wheel patterns (a circular rim with spokes extending radially from the center of the wheel to the rim). This is due to the focus or concentration of the electron beam on the surface of the sol-gel film. Two unique results are obtained. First, the linewidths of the wheels are about 100 nanometers, and provide positive relief on top of the mesa-like structure. This structure can be used as a nanoimprint mold (i.e., a nano-molding tool) to emboss only the wheel lines into a thin polymer film. The second result is that the areas of the mesa-like structure that were not directly written upon with the electron beam (i.e., the areas between the spokes and rim, and the areas outside of the rim that are immediately adjacent the rim) formed a relatively large structure. Thus, the processes of the invention have utility in rapidly writing large structures (e.g., long waveguides), and may allow direct fabrication of micromolds with tailored surface properties. For example, a pure TEOS sol-gel film may be patterned with an electron beam to rapidly form a waveguide having properties that are substantially the same as a glass waveguide formed using more conventional methods such as flame hydrolysis deposition or chemical vapor deposition. Similarly, the electron beam curing process can be used to produce the phase-shift features of a phase-shift mask.

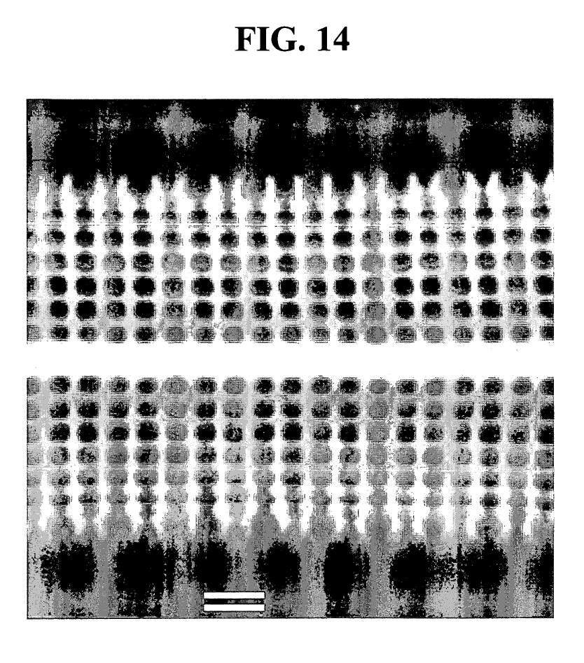

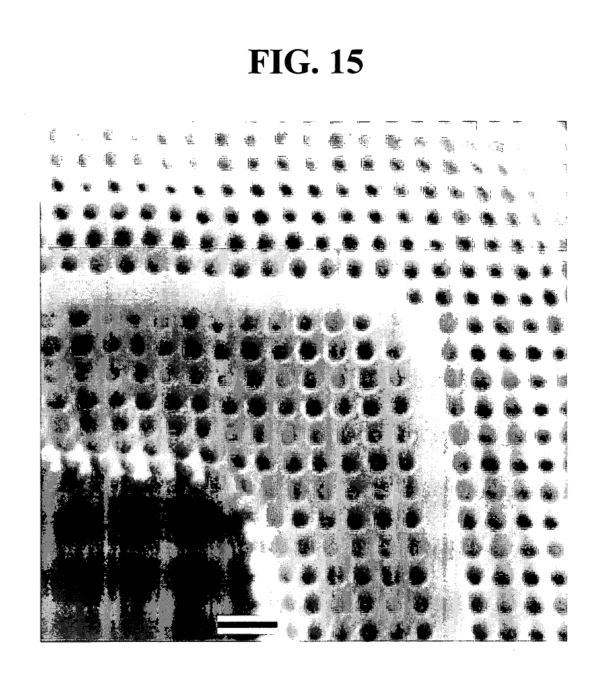

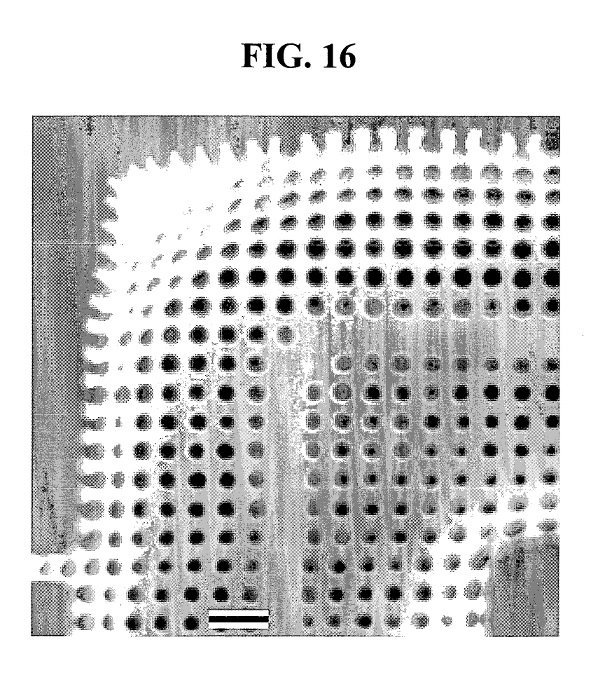

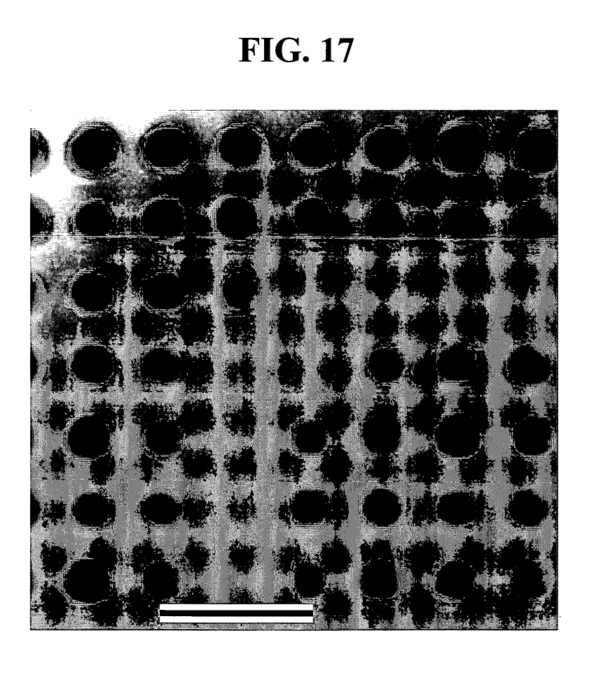

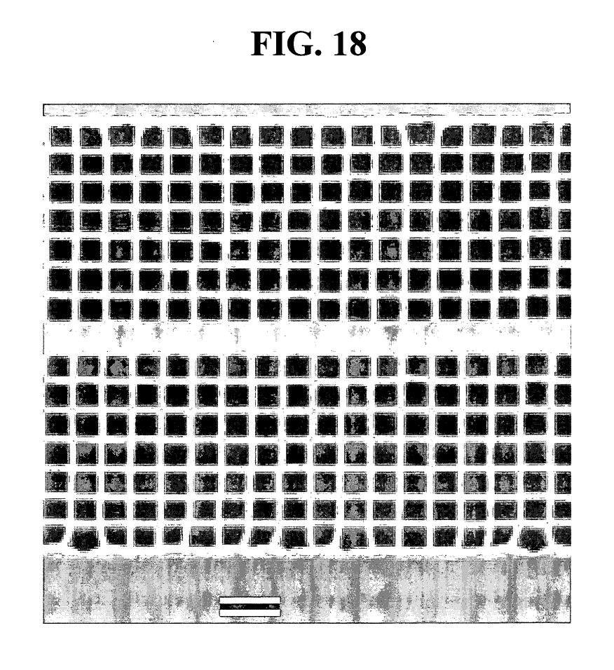

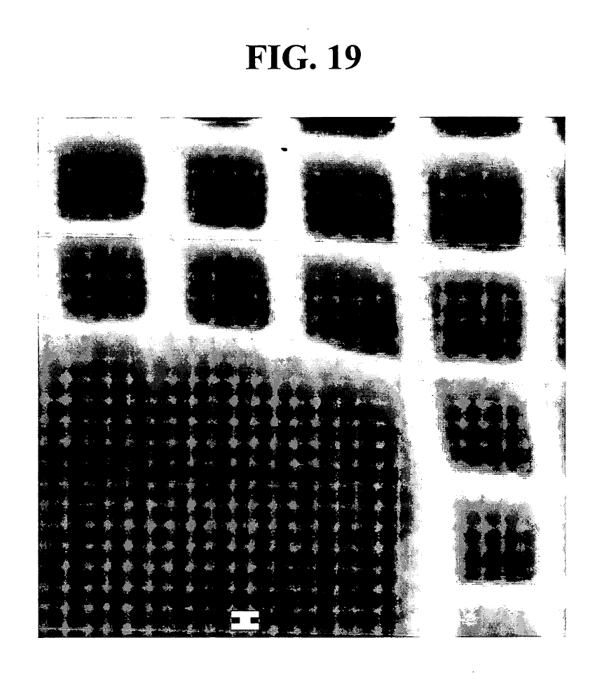

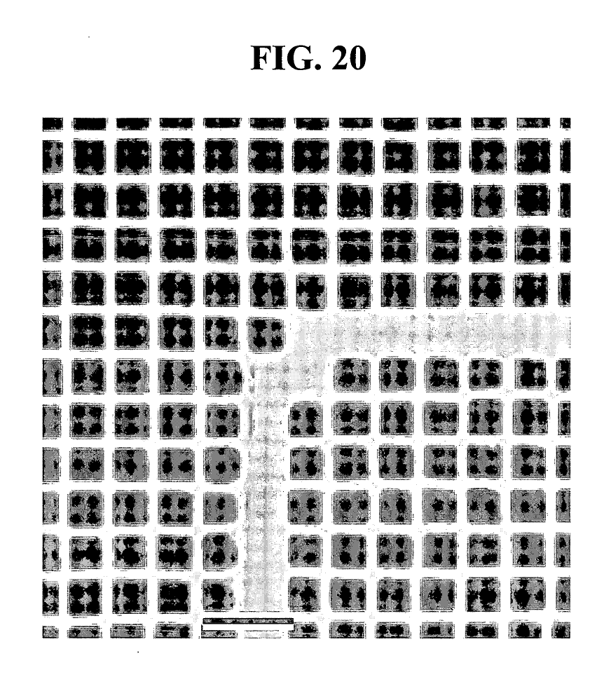

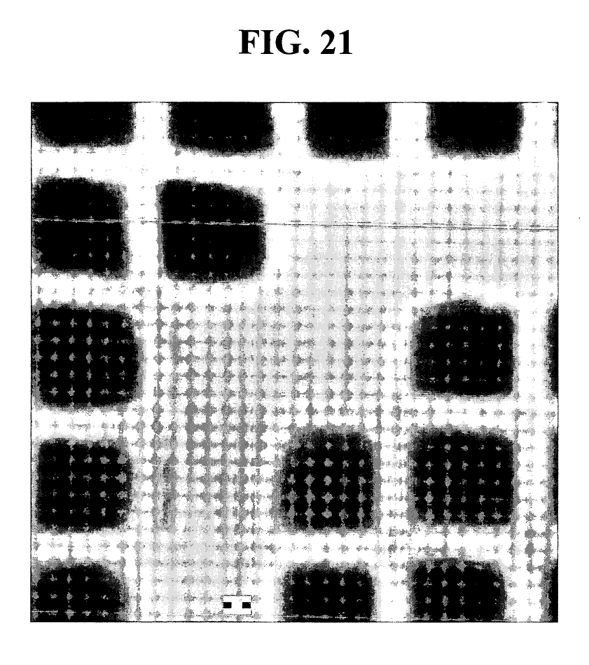

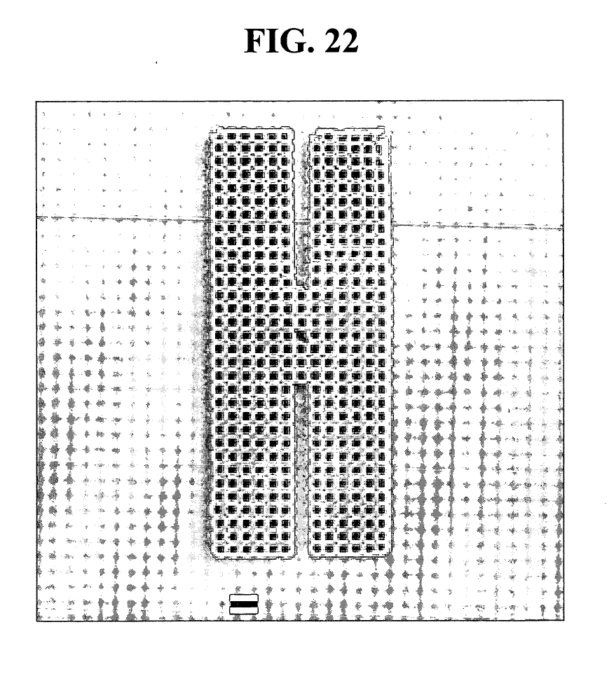

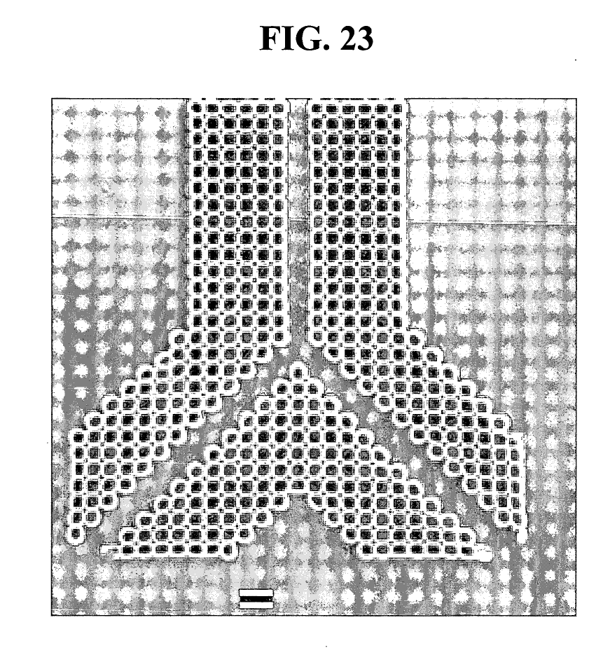

Referring particularly to FIGS. 14-23, photonic crystal waveguide structures fabricated using the electron-beam cured sol-gel photomask technique according to the present invention are shown in FIGS. 14-17, and the sol-gel photomasks utilized to prepare photonic crystal structures are shown in FIGS. 18-23. It may be seen that each fabrication process can produce photomasks and waveguide paths having a lattice or array of holes (or “wells”) and wall structures disposed on opposing sides of the waveguide, with the side walls of the holes and walls evidencing good depth, side wall smoothness, and verticality. The examples shown in FIGS. 14-17 depict photonic crystals having generally circular holes, whereas FIGS. 18-21 depict photomasks having a more rectangular configuration of substantially similar pitch (hole-to-hole center spacing) and thin wall thickness. It may be appreciated that a wide variety of suitable photonic crystal waveguide structures of the desired shape, pitch, wall thickness, and array or lattice structure may be fabricated using the process of the present invention, and used to achieve any number of photonic crystal device or waveguide patterns, such as the right-angle bends shown in FIGS. 14-21, X- and Y-splits for couplers or switches as shown in FIGS. 22 and 23, or any other pattern or array that might be suitable and appropriate to accomplish desired light-guiding properties. It may also be readily appreciated that the method of the present invention may be utilized to fabricate other types of photonic crystal structures, such as a waveguide having an array of rods (rather than holes or wells) disposed on opposing sides of the waveguide, and other patterns conventionally utilized in fashioning photonic crystal structures. It is also understood that the method of the present invention may lead to the fabrication of new and unique photonic crystal waveguide structures and patterns (particularly considering multi-layer or three-dimensional photonic crystal structures or waveguide patterns otherwise requiring repeated or overlapping lithographic and etching steps) that would be impracticable or impossible to achieve using conventional patterning and etching processes with silica-on-insulator materials.

Further background information relevant to sol-gel compositions, the formation of sol-gel films, methods for patterning, curing, and etching of such sol-gels, and the fabrication of waveguides and other structures using sol-gels are contained in U.S. patent application Ser. No. 09/319,800 (filed Dec. 12, 1997) and Ser. No. 09/494,073 (filed Jan. 28, 2000), as well as the U.S. patent application Ser. No. 09/641,358 of Hancock, Ukrainczuk, and Sewalt filed on Aug. 17, 2000 entitled Direct Writing of Waveguides in Sol-Gels, which are each incorporated herein by reference as though fully set forth.

It will be apparent to those skilled in the art that various modifications and alterations can be made to the present invention without departing from the scope and spirit of the invention. Thus, it is intended that the present invention cover the modifications and variations of this invention provided they come within the scope of the appended claims and their equivalents.

1. A mask having a pattern P₀ transferable onto an image-receiving substrate when subjected to illumination radiation in a lithographic process, comprising a substrate S₀ bearing on a surface thereof patterned phase shift features P₁ formed by a cured sol-gel material, wherein the sol-gel material has a refractive index n₁ at the wavelength of the illumination radiation λ and a thickness d.

2. A mask in accordance with claim 1, wherein d·(n₁−n₀)≈λ/2, where n₀ is the refractive index of the medium in which the mask is placed when being used.

3. A mask in accordance with claim 1, wherein at least part of the phase shift features is a grating having a pitch of less than 300 nm.

4. A mask in accordance with claim 3, wherein d·(n₁−n₀)≈λ/2.

5. A mask in accordance with claim 1 further comprising pattern features P₂ formed by layers of materials opaque or attenuating to the illumination radiation used in the lithographic process.

6. A mask in accordance with claim 5, wherein at least part of the features P₂ is formed by materials attenuating to the illumination radiation used in the lithographic process, and the thickness d₂ and refractive index n₂ of these features are chosen such that d₂·(n₂−n₀)≈λ/2, where n₀ is the refractive index of the medium in which the mask is placed when being used.

7. A mask in accordance with claim 5, wherein at least part of features P₂ is formed by Cr or modified Cr.

8. A mask in accordance with claim 5, wherein the pattern features P₁ and P₂, when transferred together to the image-receiving substrate during the lithographic process, supplement and/or correct each other to form the desired image on the image-receiving substrate.

9. A mask in accordance with claim 1, wherein the substrate S₀ is a plate having flat surfaces made of fused silica, doped fused silica or low thermal expansion glass-ceramic materials.

10. A mask in accordance with claim 1, wherein the cured sol-gel material is obtained by electron beam curing a sol-gel composition of at least one precursor material comprising at least one hydrolysable compound (I) having the following formula
Rₘ-M-Xₙ (I),
where M is a metal or metalloid having a valence of m+n, R independently is a non-hydrolysable group, X is a hydrolysable group, m is an integer from 0 to m+n−1, inclusive, and n is an integer from 1 to m+n, inclusive.

11. A mask in accordance with claim 10, wherein M is selected from the group consisting of Si, Ti, Al, Ge, Ta, B, Ga, Zr and Sb.

12. A mask in accordance with claim 10, wherein R independently is an optionally fluorinated C₁-C₁₂ hydrocarbon group.

13. A mask in accordance with claim 10, wherein X independently is selected from hydrogen, hydroxy, chlorine and OR′, where R′ is a C₁-C₄ alkyl group.

14. A mask in accordance with claim 10, wherein the precursor material of the sol-gel composition comprises 3,3,3-trifluoropropyl trimethoxysilane.

15. A mask in accordance with claim 10, wherein the precursor material of the sol-gel composition comprises at least one compound (II) which is a compound (I) in which m=0.

16. A mask in accordance with claim 15, wherein the precursor material of the sol-gel composition comprises at least one compound (III) which is a compound (I) in which R is independently an organic group, and m≧1.

17. A mask in accordance with claim 15, wherein the precursor material of the sol-gel composition comprises at least one compound (IV) which is a compound (I) in which R is independently a fluorinated alkyl or phenyl group, and m≧1.

18. A mask in accordance with claim 17, wherein the molar ratio of compounds (II) to (IV) is at least 50:50.

19. A mask in accordance with claim 17, wherein the molar ratio of compounds (II) to (IV) is at least 70:30.

20. A process for making a phase-shift mask having a pattern P₀ transferable onto an image-receiving substrate when subjected to illumination radiation in a lithographic process having a wavelength λ, said pattern P₀ including a phase-shift pattern P₁, comprising the following steps:
(a) providing a substrate S₀ transparent to the lithographic wavelength λ of the lithographic process in which the mask is used;
(b) depositing on a surface of S₀ a sol-gel film S₁ prepared from at least one precursor material comprising at least one hydrolysable compound (I) having the following formula
Rₘ-M-Xₙ (I),
where M is a metal or metalloid having a valence of m+n, R independently is a non-hydrolysable group, X is a hydrolysable group, m is an integer from 0 to m+n−1, inclusive, and n is an integer from 1 to m+n, inclusive;
(c) selectively curing part of the sol-gel film S₁ by exposing the film S₁ selectively to an electron beam, whereby producing a film S₂ consisting of (i) cured parts having the pattern P₁ of desired phase shift features having a refractive index n₁ and a thickness d, and (ii) parts P₃ that are not electron beam cured;
(d) contacting the film S₂ with a solvent to remove the parts P₃ that are not electron beam cured; and
(e) optionally, forming additional pattern features P₂ on the substrate S₀ of materials opaque or attenuating to the illumination radiation.

21. A process in accordance with claim 20, wherein the thickness d and the refractive index n₁ of the cured parts P₁ having the pattern of the desired phase shift features P₁ are chosen such that d·(n₁−n₀)≈λ/2, where n₀ is the refractive index of the medium in which the mask is placed when being used.

22. A process in accordance with claim 20, wherein step (e) is carried out and comprises depositing a film of a material opaque or attenuating to the illumination radiation used in the lithographic process above the upper surface of S₀ and/or P₁, depositing a photoresist on top of the opaque/attenuating film, exposing the photoresist, developing the exposed photoresist, selectively etching the opaque/attenuating film, followed by stripping the remaining photoresist, whereby additional pattern features of the opaque/attenuating material are formed.

23. A process in accordance with claim 22, wherein in step (e), where an attenuating material is used to form the additional features, its refractive index at the wavelength of the illumination radiation used in the lithographic process and its thickness are chosen such that the film creates a 180° phase shift of the illumination radiation with respect to medium in which the mask is to be used.

24. A process in accordance with claim 20, wherein the transparent substrate S₀ in step (a) is a plate having flat surfaces made of a material selected from fused silica, doped fused silica and low thermal expansion glass-ceramics.

25. A process in accordance with claim 20, wherein M is selected from the group consisting of Si, Ti, Al, Ge, Ta, B, Ga, Zr and Sb.

26. A process in accordance with claim 20, wherein R is independently an optionally fluorinated C₁-C₁₂ hydrocarbon group.

27. A process in accordance with claim 20, wherein X is independently a group selected from hydrogen, hydroxy, chlorine and OR′, where R′ is a C₁-C₄ alkyl group.

28. A process in accordance with claim 20, wherein the precursor material of the sol-gel composition comprises 3,3,3-trifluoropropyl trimethoxysilane.

29. A process in accordance with claim 20, wherein the precursor material of the sol-gel composition comprises at least one compound (II) which is a compound (I) in which m=0.

30. A process in accordance with claim 29, wherein the precursor material of the sol-gel composition comprises at least one compound (III) which is a compound (I) in which R is independently an organic group, and m≧1.

31. A process in accordance with claim 29, wherein the precursor material of the sol-gel composition comprises at least one compound (IV) which is a compound (I) in which R is independently a fluorinated alkyl or phenyl group, and m≧1.

32. A process in accordance with claim 31, wherein the molar ratio of compounds (II) to (IV) is at least 50:50.

33. A process in accordance with claim 31, wherein the molar ratio of compounds (II) to (IV) is at least 70:30.

34. A process in accordance with claim 20, wherein step (e) is carried out after steps (b), (c) and (d).

35. A process in accordance with claim 20, wherein step (e) is carried out prior to step (b).
